(19) United States
(12) Patent Application Publication
(10) Pub. No.: US 2025/0279136 A1
(43) Pub. Date: Sep. 4, 2025

(54) DATA SELECTION APPARATUS FOR SRAM ARRAY, STORAGE SYSTEM, AND SYSTEM ON CHIP

(71) Applicant: Shenzhen MicroBT Electronics Technology Co., Ltd., Nanshan District Shenzhen, Guangdong (CN)

(72) Inventors: Yongzhi LV, Nanshan District Shenzhen, Guangdong (CN); Zhijun FAN, Nanshan District Shenzhen, Guangdong (CN); Jianneng SHOU, Nanshan District Shenzhen, Guangdong (CN); Zuoxing YANG, Nanshan District Shenzhen, Guangdong (CN)

(73) Assignee: Shenzhen MicroBT Electronics Technology Co., Ltd., Nanshan District Shenzhen, Guangdong (CN)

(21) Appl. No.: 18/848,442

(22) PCT Filed: Jul. 12, 2024
(86) PCT No.: PCT/CN2024/105088

§ 371 Date: Sep. 18, 2024

(30) Foreign Application Priority Data
Sep. 1, 2023 (CN) 202311118068.5

(51) Int. Cl. G11C 11/413

(52) U.S. Cl. CPC G11C 11/413

(57) ABSTRACT

Embodiments of the present disclosure provide a data selection apparatus for a static random-access memory (SRAM) array, a storage system, and a system on chip (SOC). The data selection apparatus includes: a multiplexer (MUX) array, comprising a plurality of MUXs; and a D flip-flop array, comprising a plurality of D flip-flops, wherein the D flip-flop array is arranged inside the MUX array; an input of the MUX array is connected to an output of the SRAM array; an output of the MUX array is connected to a bus; the MUX array is configured to select an output channel for outputting storage data in the SRAM array; and a D flip-flop being arranged on an output channel, is configured to truncate a timing path of the output channel.

### CROSS REFERENCE

This disclosure claims priority to Chinese Patent Application No. 202311118068.5, entitled “Data Selection Apparatus for SRAM Array, Storage System, and System on Chip” filed on Sep. 1, 2023, which is incorporated by reference in its entirety.

### TECHNICAL FIELD

The present disclosure relates to the field of data storage, and more particularly to a data selection apparatus for a static random-access memory (SRAM) array, a storage system, and a system on chip (SOC).

### BACKGROUND

SRAM is commonly used as a storage apparatus in chip design. Due to constraints in the manufacturing process of SRAM, the capacity of a single SRAM is typically limited. SOC has a great demand for SRAM, and a plurality of banks of SRAMs are typically employed to achieve large-space storage. However, due to the large distance between output data of SRAM and the control logic, traces are much long, so that the timing delays occur in the output data. Hence, timing convergence in the backend becomes difficult.

Currently, in frontend design, a D flip-flop is typically connected directly to each SRAM data output port, and the timing delays of the output data are clear up at the D flip-flops. However, this kind of processing needs to arrange a large number of D flip-flops, resulting in high resource costs and making it difficult to simplify the hardware structure.

### SUMMARY

The embodiments of the present disclosure provide a data selection apparatus for an SRAM array, a storage system, and a SOC.

In one aspect, the embodiments of the present disclosure provide a data selection apparatus for an SRAM array, including:
a multiplexer (MUX) array, comprising a plurality of MUXs; and
a D flip-flop array, comprising a plurality of D flip-flops, wherein
   the D flip-flop array is arranged inside the MUX array;
   an input of the MUX array is connected to an output of the SRAM array;
   an output of the MUX array is connected to a bus;
   the MUX array is configured to select an output channel for outputting storage data in the SRAM array; and
   a D flip-flop being arranged on an output channel, is configured to truncate a timing path of the output channel.

In another aspect, the embodiments of the present disclosure further provide a storage system, including:
an SRAM array, including a plurality of SRAM banks, each SRAM bank including a plurality of SRAMs;
a multiplexer (MUX) array, comprising a plurality of MUXs; and
a D flip-flop array, comprising a plurality of D flip-flops, wherein
   the D flip-flop array is arranged inside the MUX array;
   an input of each MUX is connected to an output of a SRAM bank corresponding to the respective MUX;
   an output of the MUX array is connected to a bus;
   the MUX array is configured to select an output channel for outputting storage data in the SRAM array; and
   a D flip-flop being arranged on an output channel, is configured to truncate a timing path of the output channel.

In another aspect, the embodiments of the present disclosure further provide a SOC, including the above data selection apparatus for an SRAM array, or the above storage system.

### BRIEF DESCRIPTION OF THE DRAWINGS

FIG. 1 is an exemplary structural diagram of an SRAM array;

FIG. 2 is an exemplary structural diagram of a data selection apparatus for an SRAM array according to an embodiment of the present disclosure;

FIG. 3 is an exemplary structural diagram of an SRAM array and a MUX array according to an embodiment of the present disclosure; and

FIG. 4 is an exemplary diagram of arranging a D flip-flop array in a MUX array according to an embodiment of the present disclosure.

### DESCRIPTION OF EMBODIMENTS

To make the purpose, technical solution, and advantages of the present disclosure clearer, the following is a further detailed description of the present disclosure combined with the drawings.

For simplicity and clarity of description, the solutions of the present disclosure are set forth below by describing several representative embodiments. Numerous details of the embodiments are set forth merely to facilitate an understanding of the aspects of the present disclosure. However, it will be apparent that the technical solution of the present disclosure may be implemented without being limited to these details. To avoid unnecessarily obscuring aspects of the present disclosure, some embodiments have not been described in detail, but rather have been given a framework. Hereinafter, “include” means “including but not limited to”, “according to” means “at least according to, but not limited to only according to”. Given the linguistic conventions of Chinese, where the quantity of a component is not specified below, it means that the component may be one or more, or it may be understood as at least one.

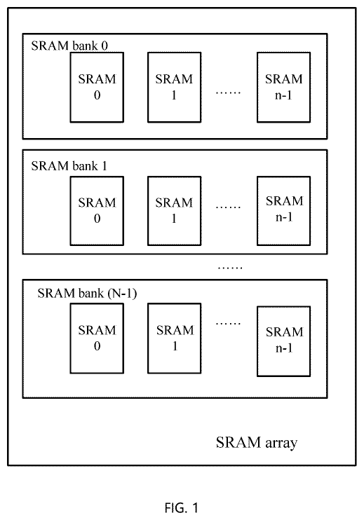

An SRAM array typically includes a plurality of SRAM banks, and each SRAM bank includes a plurality of SRAMs. FIG. 1 is an exemplary structural diagram of an SRAM array; As shown in FIG. 1, the SRAM array includes N SRAM banks, namely, SRAM bank 0, SRAM bank 1, SRAM bank 2 . . . SRAM bank (N-1). Each SRAM bank includes n SRAMs, namely, SRAM 0, SRAM 1, SRAM 2 . . . SRAM n-1. Therefore, the SRAM array includes n*N SRAMs in total.

When the bus reads the SRAM array, the data of one of the SRAM banks is selected for output. In the related art, for each SRAM bank, D flip-flops are directly connected to the data output port of the SRAM bank to truncate the timing path of the data transmission of the SRAM bank, thereby facilitating timing convergence. Therefore, a total of at least N D flip-flops need to be connected to the SRAM array.

In the embodiments of the present disclosure, the MUX has an function of selecting data from a plurality of input data and forwarding the selected data. Using this function of the MUX, the MUX and the D flip-flop are combined. As a result, inside the MUX array, using the D flip-flop array, the timing delay of the output data of the SRAM is eliminated, which can solve the timing convergence problem, and at the same time reduce the resource requirement of the D flip-flop.

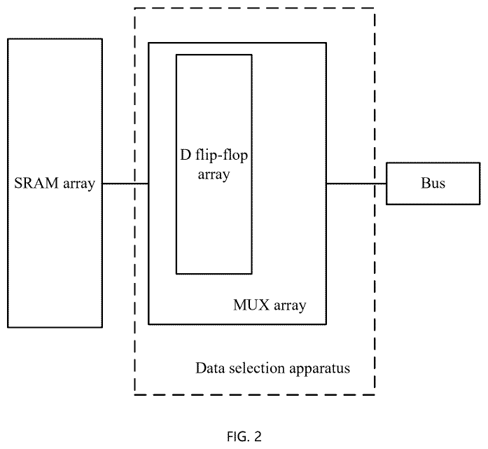

FIG. 2 is an exemplary structural diagram of a data selection apparatus for an SRAM array according to an embodiment of the present disclosure. In FIG. 2, the data selection apparatus for an SRAM array includes:
a MUX array, including a plurality of MUXs; and
a D flip-flop array, including a plurality of D flip-flops, wherein
   the D flip-flop array is arranged inside the MUX array;
   an input of the MUX array is connected to an output of the SRAM array;
   an output of the MUX array is connected to a bus;
   the MUX array is configured to select an output channel for outputting storage data in the SRAM array; and
   a D flip-flop being arranged on an output channel, is configured to truncate a timing path of the output channel.

Based on the cooperation between the MUX array and the D flip-flop array, the above data selection apparatus for an SRAM array is able to improve the timing delay, save the D flip-flop resource, and simplify the hardware structure.

Each MUX in the MUX array can select one output channel from a plurality of output channels of the SRAM array. When the bus reads the SRAM array, the MUX array selects the output data of an SRAM bank in the SRAM array and outputs the data to the bus through the output of the MUX array.

The D flip-flop is an information storage component with a memory function and two stable states, and it is a basic logic unit used to constitute a variety of timing circuits. When a trigger edge arrives, the D flip-flop saves the value at the input, and this value is irrelevant to a current storage value. Between two valid pulse edges, the change at the input of the D flip-flop does not affect the value stored in the D flip-flop. Based on the above characteristics of the D flip-flop, the D flip-flop may be used to truncate the timing path of data transmission, which is beneficial to the timing convergence of the chip.

In the embodiments of the present disclosure, the number of D flip-flops deployed can be significantly reduced by arranging the D flip-flop array inside the MUX array, instead of directly connecting the data output port of each SRAM bank to the D flip-flop. Moreover, the D flip-flop which is combined with the multiplexing function of the MUX can truncate the timing path of each output channel for outputting to the bus, thus ensuring timing convergence.

In one embodiment, the plurality of MUXs in the MUX array are multi-stage MUXs; the plurality of D flip-flops in the D flip-flop array are arranged in parallel at the same positions between MUXs at adjacent stages in the MUX array. Considering that the timing delay characteristics of each output channel are generally the same or similar, arrangement difficulty can be reduced by arranging a plurality of D flip-flops in parallel at the same positions between the MUXs at adjacent stages.

In one embodiment, the plurality of MUXs in the MUX array are multi-stage MUXs; the plurality of D flip-flops in the D flip-flop array are arranged in parallel at different positions in the MUX array. Considering that the timing delay characteristics of each output channel may be different (for example, the transmission path length of each output channel may be different), it is necessary to arrange the plurality of D flip-flops in parallel at different positions in the MUX array to truncate the timing path of each output channel.

In one embodiment, the plurality of MUXs in the MUX array are multi-stage MUXs; the D flip-flop array includes first portions and second portions.

The first portion is arranged in parallel at the same positions between MUXs at adjacent stages in the MUX array.

The second portion is arranged in parallel at different positions in the MUX array.

For the output channels with the same timing delay characteristics, the first portion is arranged in parallel at the same positions between the MUXs at adjacent stages, so that the timing paths of these output channels with the same timing delay characteristics may be truncated and the arrangement difficulty may be reduced.

Further, for output channels with different timing delay characteristics, the second portion is arranged in parallel at different positions in the MUX array, so that the timing paths of these output channels with different timing delay characteristics may be truncated.

In one embodiment, for each output channel from the output of the SRAM array to the bus, a first timing delay along the respective output channel to a first D flip-flop is less than a predetermined timing delay threshold, and a difference between the first timing delay and the predetermined timing delay threshold is less than a predetermined difference threshold.

The arrangement position of the first D flip-flop simultaneously satisfies the following conditions:
(1) The first timing delay to the first D flip-flop is less than a predetermined timing delay threshold.
(2) A difference between the first timing delay to the first D flip-flop and the predetermined timing delay threshold is less than a predetermined difference threshold.

The predetermined timing delay threshold may be a fixed value or an adjustable value.

Similarly, the difference threshold may be a fixed value or an adjustable value.

Preferably, the predetermined timing delay threshold is determined based on the maximum operating frequency of the SRAM array. For example, assuming that the maximum operating frequency of the SRAM array is 250 MHz, the predetermined timing delay threshold may be 1/250 MHZ=4 nanoseconds (ns).

Therefore, this arrangement mode for the first D flip-flop can not only ensure the timing convergence to the first D flip-flop but also ensure that the arrangement position of the first D flip-flop is far away from the output of the SRAM array as much as possible, thereby minimizing the number of D flip-flops. For example, a timing delay to the first D flip-flop may be measured using a timing delay measurement tool (such as Prime Time, a static timing analysis tool).

In one embodiment, for each output channel from the output of the SRAM array to the bus, a second timing delay along the respective output channel between any two closest D flip-flops is less than a predetermined timing delay threshold, and a difference between the second timing delay and the predetermined timing delay threshold is less than a predetermined difference threshold.

The arrangement positions of any two closest D flip-flops simultaneously satisfy the following conditions:
(1) A second timing delay between any two closest D flip-flops is less than a predetermined timing delay threshold.
(2) A difference between the second timing delay between any two closest D flip-flops and the predetermined timing delay threshold is less than a predetermined difference threshold.

The predetermined timing delay threshold may be a fixed value or an adjustable value.

Similarly, the difference threshold may be a fixed value or an adjustable value.

Preferably, the predetermined timing delay threshold is determined based on the maximum operating frequency of the SRAM array. For example, assuming that the maximum operating frequency of the SRAM array is 250 MHZ, the predetermined timing delay threshold may be 1/250 MHZ=4 nanoseconds (ns).

Therefore, the timing convergence can be ensured, and the distance between any two closest D flip-flops can be ensured as far as possible, thus minimizing the number of D flip-flops. For example, a timing delay between any two closest D flip-flops may be measured using a timing delay measurement tool (such as Prime Time, a static timing analysis tool).

The embodiments of the present disclosure further provide a storage system, including:
an SRAM array, including a plurality of SRAM banks, each SRAM bank including a plurality of SRAMs;
a MUX array, including a plurality of MUXs; and
   a D flip-flop array, including a plurality of D flip-flops, wherein
   the D flip-flop array is arranged inside the MUX array;
   an input of each MUX is connected to an output of a SRAM bank corresponding to the respective MUX;
   an output of the MUX array is connected to a bus;
   the MUX array is configured to select an output channel for outputting storage data in the SRAM array; and
   a D flip-flop being arranged on an output channel, is configured to truncate a timing path of the output channel.

In one embodiment, the MUX array includes multi-stage MUXs; the plurality of D flip-flops are arranged in parallel at the same positions between MUXs at adjacent stages in the MUX array; alternatively, the plurality of D flip-flops are arranged in parallel at different positions in the MUX array.

In one embodiment, the MUX array includes multi-stage MUXs. The D flip-flop array includes first portions and second portions; the first portion is arranged in parallel at the same positions between MUXs at adjacent stages in the MUX array; the second portion is arranged in parallel at different positions in the MUX array.

In one embodiment, for each output channel from the output of the SRAM array to the bus, a first timing delay along the respective output channel to a first D flip-flop is less than a predetermined timing delay threshold, and a difference between the first timing delay and the predetermined timing delay threshold is less than a predetermined difference threshold.

In one embodiment, for each output channel from the output of the SRAM array to the bus, a second timing delay along the respective output channel between any two closest D flip-flops is less than a predetermined timing delay threshold, and a difference between the second timing delay and the predetermined timing delay threshold is less than a predetermined difference threshold.

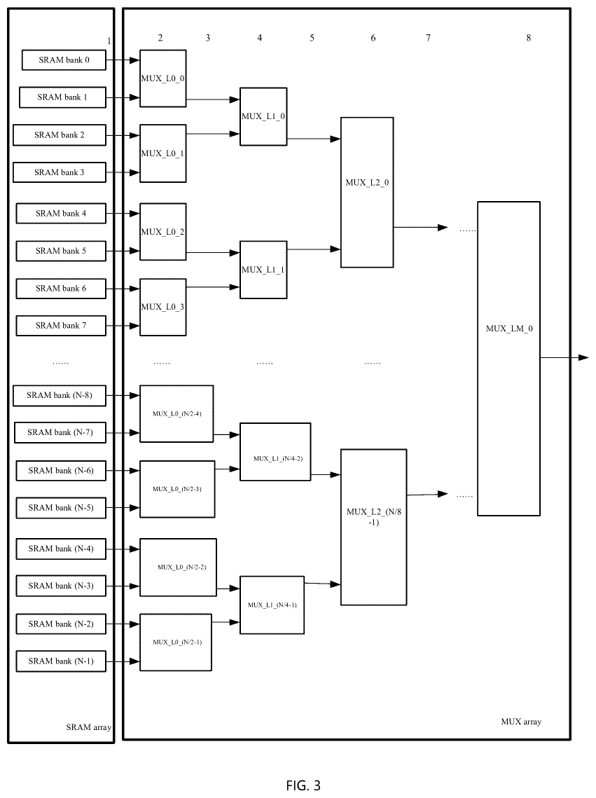

FIG. 3 is an exemplary structural diagram of an SRAM array and a MUX array according to an embodiment of the present disclosure.

In FIG. 3, the SRAM array includes N SRAM banks, namely, SRAM bank 0, SRAM bank 1, SRAM bank 2, SRAM bank 3 . . . SRAM bank (N-1).

The MUX array includes (M+1) stages, namely, a first-stage MUX (MUX_L0_0, MUX_L0_1, MUX_L0_2, MUX_L0_3 . . . MUX_L0_(N/2-1)) at position 2, a second-stage MUX (MUX_L1_0, MUX_L1_1 . . . MUX_L1_(N/4-1)) at position 4, a third-stage MUX (MUX_L2_0, MUX_L2_1 . . . MUX_L2_(N/8-1)) at position 6, and the like.

In the embodiments of the present disclosure, each MUX in the MUX array is implemented as a one-out-of-two MUX, that is, having two data inputs and one data output. The two data inputs of the MUX in the first-stage MUX are connected to two corresponding SARM banks in the SRAM array, respectively; the data outputs of the intermediate-stage MUX are connected to the data inputs of the next-stage MUX, respectively; the data output of the last-stage MUX is connected to the bus.

A timing delay measurement tool (such as Prime Time) may be used to measure the timing delay parameters of each segment path in all output channels from the SRAM bank to multi-stage MUXs to the bus. The rightmost position (i.e. as close to the bus as possible) that can meet the requirement of the predetermined timing delay threshold is determined in the output channel, and a D flip-flop is inserted at this position. The advantage is that the resource cost of inserting a D flip-flop at this position is minimal.

If the timing delay of the right path after the D flip-flop is inserted still does not meet the requirement of the predetermined timing delay threshold, the D flip-flop may be continuously inserted in the right path.

Specific insertion methods of the D flip-flops may include the following:

(1) A plurality of D flip-flops may be inserted in parallel at positions such as position 3 (i.e., between the MUX stage of position 2 and the MUX stage of position 4, the MUX stage of position 2 and the MUX stage of position 4 are adjacent stages), position 5 (i.e., between the MUX stage of position 4 and the MUX stage of position 6, the MUX stage of position 4 and the MUX stage of position 6 are adjacent stages), position 7 (i.e., between the MUX stage of position 6 and the MUX stage of position 8, the MUX stage of position 6 and the MUX stage of position 8 are adjacent stages), and the like. Since the D flip-flop corresponds to the MUX in the previous adjacent stage, the number of D flip-flops is equal to the number of MUXs in the previous adjacent stage. Together, these inserted D flip-flops form the D flip-flop array.

Assuming that the D flip-flop resource to be occupied by inserting the D flip-flop at position 1 is A bits as in the related art, when a one-out-of-two MUX is adopted according to the embodiments of the present disclosure, the insertion of the D flip-flop at position 3 needs to occupy A/2 bits, the insertion of the D flip-flop at position 5 needs to occupy A/4 bits, and the insertion of the D flip-flop at position 7 needs to occupy A/8 bits. It can be seen that the embodiments of the present disclosure significantly reduce the D flip-flop resource.

(2) A D flip-flop may be inserted at any position in the MUX array.

At this time, it is necessary to satisfy the following conditions:
A. For each output channel from the output of the SRAM array to the bus, a timing delay along the respective output channel to a first D flip-flop is less than a predetermined timing delay threshold, and a difference between the timing delay and the predetermined timing delay threshold is less than a predetermined difference threshold.
B. For each output channel from the output of the SRAM array to the bus, a timing delay along the respective output channel between any two closest D flip-flops is less than a predetermined timing delay threshold, and a difference between the timing delay and the predetermined timing delay threshold is less than a predetermined difference threshold. The D flip-flop inserted in this way can match the condition of each output channel well.

When the timing delay of the output channel is large, more D flip-flops may be inserted into the output channel; when the timing delay of the output channel is small, fewer D flip-flops may be inserted into the output channel.

Another embodiment of the present disclosure is described below by taking a storage system as an example. For a 5 MB storage system, it is assumed that the storage capacity of an SRAM is 4098 (depth)*128 (bit width)=64 (KB). Every 4 SRAMs form an SRAM bank, and the total capacity of the SRAM bank is 4098*128*4=256 (KB).

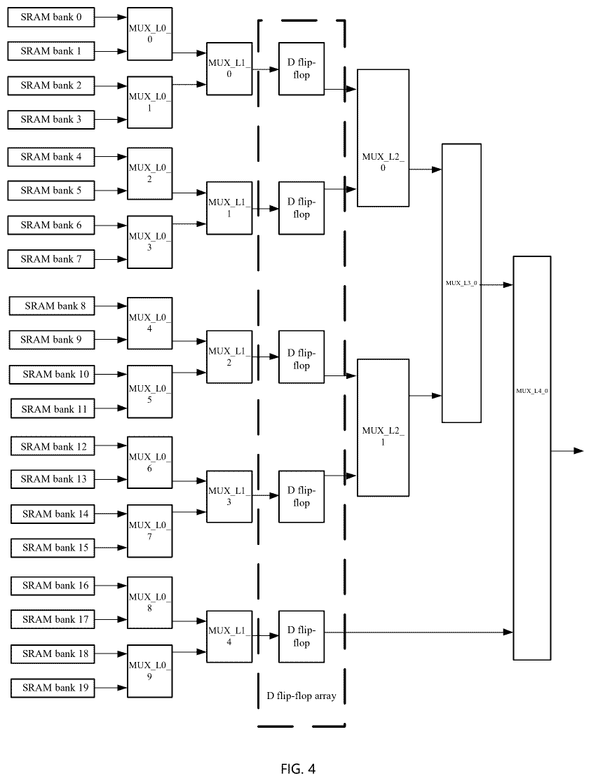

FIG. 4 is an exemplary diagram of arranging a D flip-flop array in a MUX array according to an embodiment of the present disclosure.

In FIG. 4, the MUXs in the MUX array are all implemented as one-out-of-two MUXs, i.e. each MUX has two data inputs and one data output.

The MUX array includes five stages, namely, a first-stage MUX (MUX_L0_0, MUX_L0_1, MUX_L0_2, MUX_L0_3 . . . MUX_L0_9), a second-stage MUX (MUX_L1_0, MUX_L1_1 . . . MUX_L1_4), a third-stage MUX (MUX_L2_0, MUX_L2_1), a fourth-stage MUX (MUX_L3_0), and a fifth-stage MUX (MUX_L4_0). The output of MUX_L4_0 is connected to the bus.

Five D flip-flops forming a D flip-flop array are arranged in parallel between the second-stage MUX (MUX_L1_0, MUX_L1_1 . . . MUX_L1_4) and the third-stage MUX (MUX_L2_0, MUX_L2_1), respectively. Compared with the processing method of inserting a D flip-flop for each bank of SRAM in the related art (a total of 20*128*4=10240 bits need to be inserted), the total resource of the D flip-flop array in FIG. 4 is 20*128*4/4=2560 bits, so the embodiments of the present disclosure not only solve the timing problem but also reduce the resource consumption.

In FIG. 4, a MUX array is illustrated by taking a one-out-of-two MUX as an example. In addition, the MUX may be implemented as a one-out-of-three MUX, a one-out-of-four MUX, a one-out-of-eight MUX, or the like; the embodiments of the present disclosure are not limited thereto.

When there are more inputs of MUX (i.e. when N in one-out-of-N MUX is larger), the number of MUXs in the MUX array may be reduced, and the cost may be reduced.

Further, the MUX used in the MUX array may be implemented as the same type of MUX (for example, all of them are one-out-of-four MUXs), or may be implemented as different types of MUXs (for example, one part adopts one-out-of-four MUXs, and the other part adopts one-out-of-eight MUX); the embodiments of the present disclosure are not limited thereto.

The above data selection apparatus for an SRAM array and the storage system may be applied to a SOC. The embodiment of the present disclosure further provides a SOC, including the storage system according to any one of the above embodiments or the above data selection apparatus for an SRAM array according to any one of the above embodiments.

The foregoing is merely a preferred embodiment of the present disclosure and is not intended to limit the scope of the present disclosure. Any modification, equivalent replacement, improvement, and the like made within the spirit and principles of the present disclosure shall be included in the scope of protection of the present disclosure.

1. A data selection apparatus for a static random-access memory (SRAM) array, comprising:
a multiplexer (MUX) array, comprising a plurality of MUXs; and
a D flip-flop array, comprising a plurality of D flip-flops, wherein
the D flip-flop array is arranged inside the MUX array;
an input of the MUX array is connected to an output of the SRAM array;
an output of the MUX array is connected to a bus;
the MUX array is configured to select an output channel for outputting storage data in the SRAM array; and
a D flip-flop being arranged on an output channel, is configured to truncate a timing path of the output channel.

2. The apparatus according to claim 1, wherein the plurality of MUXs are multi-stage MUXs; the plurality of D flip-flops are arranged in parallel at same positions between MUXs at adjacent stages; or,
the plurality of D flip-flops are arranged in parallel at different positions in the MUX array.

3. The apparatus according to claim 1, wherein the plurality of MUXs are multi-stage MUXs; and
the D flip-flop array comprises a first portion and a second portion, wherein
the first portion is arranged in parallel at same positions between MUXs at adjacent stages; and
the second portion is arranged in parallel at different positions in the MUX array.

4. The apparatus according to claim 1, wherein for each output channel from the output of the SRAM array to the bus, a first timing delay along the respective output channel to a first D flip-flop is less than a predetermined timing delay threshold, and a difference between the first timing delay and the predetermined timing delay threshold is less than a predetermined difference threshold.

5. The apparatus according to claim 1, wherein for each output channel from the output of the SRAM array to the bus, a second timing delay along the respective output channel between any two closest D flip-flops is less than a predetermined timing delay threshold, and a difference between the second timing delay and the predetermined timing delay threshold is less than a predetermined difference threshold.

6. A storage system, comprising:
a static random-access memory (SRAM) array, comprising a plurality of SRAM banks, each SRAM bank comprising a plurality of SRAMs;
a multiplexer (MUX) array, comprising a plurality of MUXs; and
a D flip-flop array, comprising a plurality of D flip-flops, wherein
the D flip-flop array is arranged inside the MUX array;
an input of each MUX is connected to an output of a SRAM bank corresponding to the respective MUX;
an output of the MUX array is connected to a bus;
the MUX array is configured to select an output channel for outputting storage data in the SRAM array; and
a D flip-flop being arranged on an output channel, is configured to truncate a timing path of the output channel.

7. The storage system according to claim 6, wherein the plurality of MUXs are multi-stage MUXs; the plurality of D flip-flops are arranged in parallel at same positions between MUXs at adjacent stages; or,
the plurality of D flip-flops are arranged in parallel at different positions in the MUX array.

8. The storage system according to claim 76, wherein the plurality of MUXs are multi-stage MUXs; and
the D flip-flop array comprises a first portion and a second portion, wherein
the first portion is arranged in parallel at same positions between MUXs at adjacent stages; and
the second portion is arranged in parallel at different positions in the MUX array.

9. The storage system according to claim 6, wherein for each output channel from the output of the SRAM array to the bus, a first timing delay along the respective output channel to a first D flip-flop is less than a predetermined timing delay threshold, and a difference between the first timing delay and the predetermined timing delay threshold is less than a predetermined difference threshold.

10. The storage system according to claim 6, wherein for each output channel from the output of the SRAM array to the bus, a second timing delay along the respective output channel between any two closest D flip-flops is less than a predetermined timing delay threshold, and a difference between the second timing delay and the predetermined timing delay threshold is less than a predetermined difference threshold.

11. A system on chip (SOC), comprising the data selection apparatus for a static random-access memory (SRAM) array according to claim 1, or the storage system according to claim 6.
